(19) United States
(12) Patent Application Publication
(10) Pub. No.: US 2023/0075607 A1
(43) Pub. Date: Mar. 9, 2023

(54) ARCHITECTURE AND PACKAGING FOR INTEGRATED CIRCUITS

(71) Applicant: Cisco Technology, Inc., San Jose, CA (US)

(72) Inventors: D. Brice Achkir, Livermore, CA (US); Jie Xue, Dublin, CA (US); Mark Charles Nowell, Kanata (CA)

(21) Appl. No.: 17/841,838

(22) Filed: Jun. 16, 2022

Related U.S. Application Data
(60) Provisional application No. 63/240,616, filed on Sep. 3, 2021.

(51) Int. Cl. H01L 25/16; H01L 23/538; H01L 23/498; H01L 21/48

(52) U.S. Cl. CPC H01L 25/167; H01L 23/5383; H01L 23/49894; H01L 21/4857

(57) ABSTRACT

An apparatus is provided that includes a thin-film interconnect structure that comprises one or more polymeric layers and conductive plating, a first surface of the thin-film interconnect structure being configured to receive one or more dies, and a second surface of the thin-film interconnect structure being configured to receive a substrate. A method of assembling the apparatus into an integrated circuit assembly is also provided.

### CROSS REFERENCE TO RELATED APPLICATION

This application claims priority to U.S. Provisional Application No. 63/240,616, filed Sep. 3, 2021, entitled “Next Generation CPO/NPO/ASIC Packaging,” the entirety of which is incorporated herein by reference.

### TECHNICAL FIELD

The present disclosure relates to semiconductor assembly, and in particular, to an architecture and packaging for integrated circuits.

### BACKGROUND

A high demand for semiconductors and their lack of supply has caused a shortage crisis that has impacted a variety of industries. The sourcing of dies from limited foundries is one of the issues that the industry is trying to solve. Adding to that, other critical components, such as redistribution layer (RDL) fanouts, organic substrates, and packaging assemblies that are necessary to build integrated circuits (e.g., application-specific integrated circuits (ASICs)), are also in short supply.

### BRIEF DESCRIPTION OF THE DRAWINGS

FIG. 1 is an illustration of an integrated circuit package, in accordance with a conventional technique.

FIG. 2 is a diagram depicting a workflow for the fabrication of an integrated circuit package, in accordance with a conventional technique.

FIG. 3 is a diagram depicting a workflow for the fabrication of an integrated circuit package, according to an embodiment.

FIG. 4 is a diagram depicting a workflow for the fabrication of an interconnect structure, according to an embodiment.

FIGS. 5A and 5B are diagrams depicting an interconnect structure bonded to a substrate, according to example embodiments.

FIG. 6 is a diagram of an interconnect structure that includes micro-pads and micro-bumps, according to an embodiment.

FIGS. 7A-7C are diagrams depicting a process of fabricating a co-packed optics (CPO) assembly, according to an embodiment.

FIGS. 8A-8C are diagrams depicting a process of fabricating an ASIC assembly, according to an embodiment.

FIG. 9 is a diagram depicting a workflow for the fabrication of an integrated circuit package, according to an embodiment.

FIG. 10 is an illustration of a Near Package Optics (NPO) high density interconnection (HDI) printed circuit board (PCB)-like or substrate-like building block, according to an embodiment.

FIG. 11 is an illustration of an NPO fully-assembled ASIC, according to an embodiment.

FIG. 12 is a flow chart for a method of assembling an integrated circuit package, according to an embodiment.

### DESCRIPTION OF EXAMPLE EMBODIMENTS

### Overview

An apparatus is provided that includes a thin-film interconnect structure that comprises one or more polymeric layers and conductive plating, a first surface of the thin-film interconnect structure being configured to receive one or more dies, and a second surface of the thin-film interconnect structure being configured to receive a substrate. A method of assembling the apparatus into an integrated circuit assembly is also provided.

### EXAMPLE EMBODIMENTS

A redistribution layer (RDL) is an extra metal layer on an integrated circuit that makes the integrated circuit's input/output (TO) pads available at other locations of the chip, for better access to the pads where necessary. An RDL, also referred to as a RDL fanout or interconnect layer, is disposed between the substrate and the die, and is therefore a key element in integrated circuit packaging. Conventionally, the fabrication of RDL fanouts is controlled by the same foundries that also control the die technology and other processes. Additionally, due to the nature of conventional integrated circuit fabrication techniques, RDLs are fabricated on-site at the foundries. Therefore, original equipment manufacturers (OEMs) are highly dependent on these foundries, which limits the available alternative solutions.

In addition, driven by increased density and speed on network processing units (NPUs), graphics processing units (GPUs), artificial intelligence (AI)/machine learning (ML) chips, and ASICs, substrate layer count and size are increasing significantly, which results in the substrate being a significant cost of a chip (sequential build up, longer cycle time, and lower yield). This trend has led to an industry-wide shortage on substrates, and this trend is predicted to increase in the coming years.

Other issues in the current semiconductor architecture include a substantial increase in the number of layers in organic substrates, increasing the price and limiting the number of substrate fabrication houses capable of producing the substrates. Additionally, organic substrate body size has increased due to the number of dies needed, also increasing costs while limiting the number of substrates that can be brought to market. Organic substrates with a high number of layers and/or large body sizes can suffer reliability issues such as warpage, cracking solders, and the like.

Furthermore, assembling large integrated circuits with traditional printed circuit boards (PCBs) can lead to solder reliability issues due to reflow and warpage. For example, application-specific integrated circuit (ASIC) host board design complexity has increased due to routing of high number of IOs and voltage rails, causing both signal integrity and power integrity limitations. In ASIC via fields, it is extremely difficult to route differential channels, thus limiting manufacturers to single-ended topologies due to their immunity issues. A large number of anti-pads for limiting the copper density increases the number of power shapes to compensate for the routing topologies.

With the advent of complex chip architectures such as co-packaged optics (CPOs), Near Package Optics (NPOs), a silicon photonic packaging (SPO), and other next generation optical tiles/modules, there is a desire to control the design, optimization of fabrication processes, and manufacturing of different building blocks using different strategies to reduce the overall cost, to align with OEM resiliency business plans, and to incorporate the latest technologies and processes.

Accordingly, present embodiments provide an alternative solution to a redistribution layer by providing a thin-film interconnect structure that includes multiple polymeric layers that are plated with conductive material (e.g., copper) where appropriate, to achieve any desirable fine pitch geometry for fanout-style redistribution of IOs. The thin-film interconnect structure benefits from the finer pitch geometries that are achievable using thin-film techniques. Additionally, by using a thin-film approach, present embodiments enable an interconnect structure to be fabricated in a larger panel size (e.g., larger than 300 mm wafer), off-site from the foundry that fabricates the integrated circuit. Thus, supply-chain restrictions are avoided, as the interconnect structure can be fabricated off-site and then provided in between the dies and the substrate when an integrated circuit is assembled.

Moreover, thin-film polymeric layers enable many components, such as capacitors or power management elements, to be provided in the interconnect structure rather than the substrate. Thus, present embodiments offer improvements to integrated circuits by reducing the number of the substrate layers. Accordingly, present embodiments enable the benefit of stand-alone fabrication of an interconnect structure by avoiding the conventional silicon-wafer approach, while also achieving better electrical performance compared to standard complex substrates. The improvements disclosed herein are not limited to ASICs, but can benefit any semiconductor architecture. For example, these techniques can be used in a CPO, an NPO, a central processing unit (CPU), a graphical processing unit (GPU), a network processing unit (NPU), and other next-generation semiconductor architectures

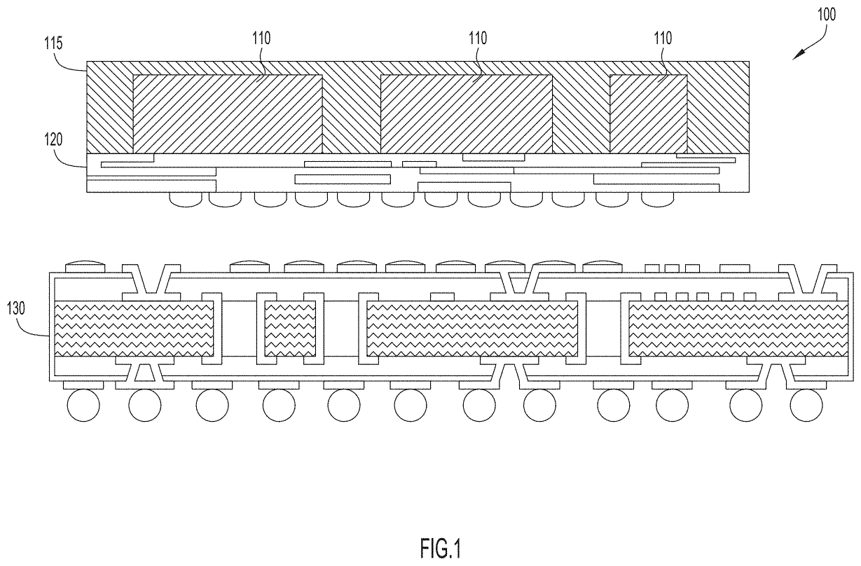

With reference made to FIG. 1, FIG. 1 is an illustration of an integrated circuit package 100, in accordance with a conventional technique. It should be understood that the separation between components is provided to facilitate the description of conventional integrated circuit package 100, and that components of a conventional integrated circuit package would be in contact with each other.

As depicted, integrated circuit package 100 includes a plurality of dies 110, a moulding compound 115, a wafer redistribution layer (wRDL) 120, and a substrate 130. Typically, a packaging assembly house assembles all of these components together. In general, substrate 130 is an organic epoxy-based sequential build-up substrate (e.g., fabricated one layer at a time) or ceramic based co-fired substrate. The moulding compound 115 can include a glass-fiber reinforced thermoset polymer material or other suitable moulding material. Even with advances in fabrication processes, the technologies and the materials of substrates still suffer from many limitations. With the use of a large body substrate, e.g., for a CPO, not many fabrication substrate houses can fabricate substrate sizes that exceed a 110 mm by 110 mm threshold with 9/2/9 layers. With very limited understanding of what fabrication yields will be, costs are driven up. Additionally, there are limited suppliers from which to choose. In addition to uncertainties around volume production readiness, quality and reliability criteria impose supply base constraints that are hard to overcome.

Moreover, on the performance side, combining the high insertion loss or dissipation factor (Df) of the materials (when compared to ultra-low loss for PCB) and the high copper surface roughness (compared to, for example, the smoothness of PCB hyper very low profile (HVLP) copper foil) the losses of the traces tend to be high, increasing the power consumption due to the many taps for equalizing and compensating the induced and intrinsic losses and inter-symbol interference impairments. With conventional substrates, the losses in the substrate exceed 4 dB, even with the use of the latest dielectric materials.

Still referring to FIG. 1, wRDL 120 includes a mix of metal and dielectric layers provided on the surface of a wafer to reroute the tight pitch of each die 110 to a larger pitch. Typically, die 110 is molded and wRDL 120 is fabricated with connections to each die 110, an approach referred to as die-first fabrication. Die-first techniques limit the testing of each element on their own and have significant yield implications when a wRDL layer has fabrication defects, accordingly increasing the overall costs of manufacturing (e.g., as dies have to be discarded if a wRDL has fabrication defects). Foundries typically do not disclose how they mount dies to RDLs, and generally keep the process a secret. In fact, die-and-RDL assemblies are mounted so tightly together that it is very difficult to build a die in one foundry and RDL in another foundry, thus enabling foundries to maintain a vertically-integrated business. From a performance side, due to routing limitations and the number of accessible layers, the losses tend to increase with the increase of IO count and the number dies to be interconnected.

To solve many manufacturability and multi-vendor constraints, an ASIC according to one or more embodiments presented herein comprises building blocks that can be manufactured by different suppliers, allowing blocks from different suppliers to be assembled.

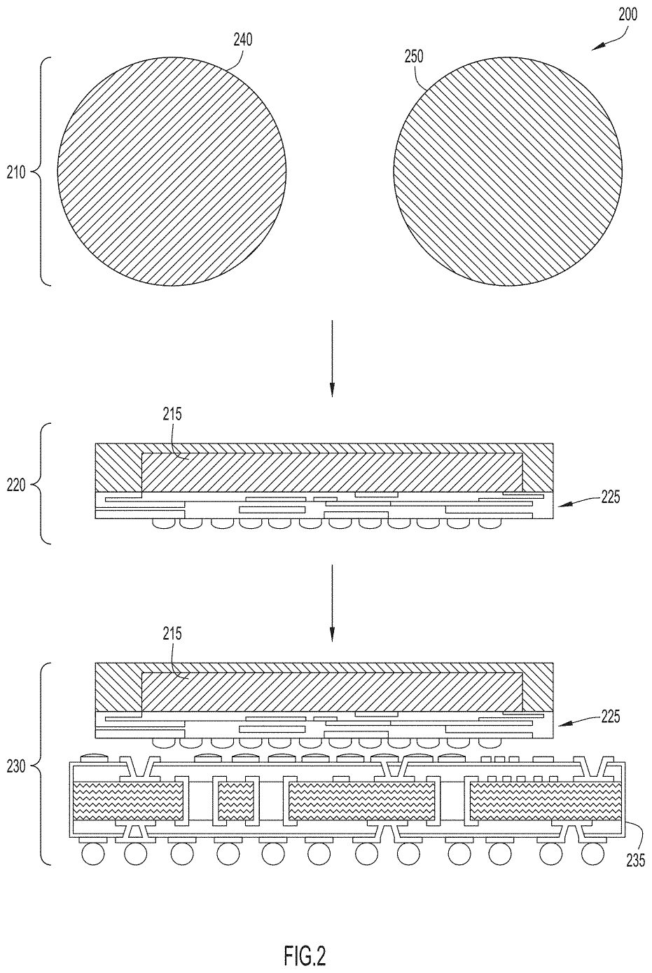

Now with reference to FIG. 2, a diagram depicting a workflow 200 is shown for the fabrication of an integrated circuit package, in accordance with a conventional technique. Workflow 200 includes a first phase 210, a second phase 220, and a third phase 230.

At the first phase 210, a wafer 240 and molded wafer 250 are molded to provide one or more dies (e.g., die 215). At the second phase 220, wRDL 225 is fabricated on the molded wafer (e.g., molded wafer 250 of phase 210) thereby providing die 215. Accordingly, due to the constraints of conventional fabrication techniques, wRDL 225 must be assembled at the same location (fabrication facility) that die 215 is fabricated.

At the third phase 230, the die 215 and wRDL 225 assembly is soldered to substrate 235, which may be an organic build-up substrate or other substrate. Thus, phases 210-230 depict a conventional technique for fabricating integrated circuit packages in a die-first manner.

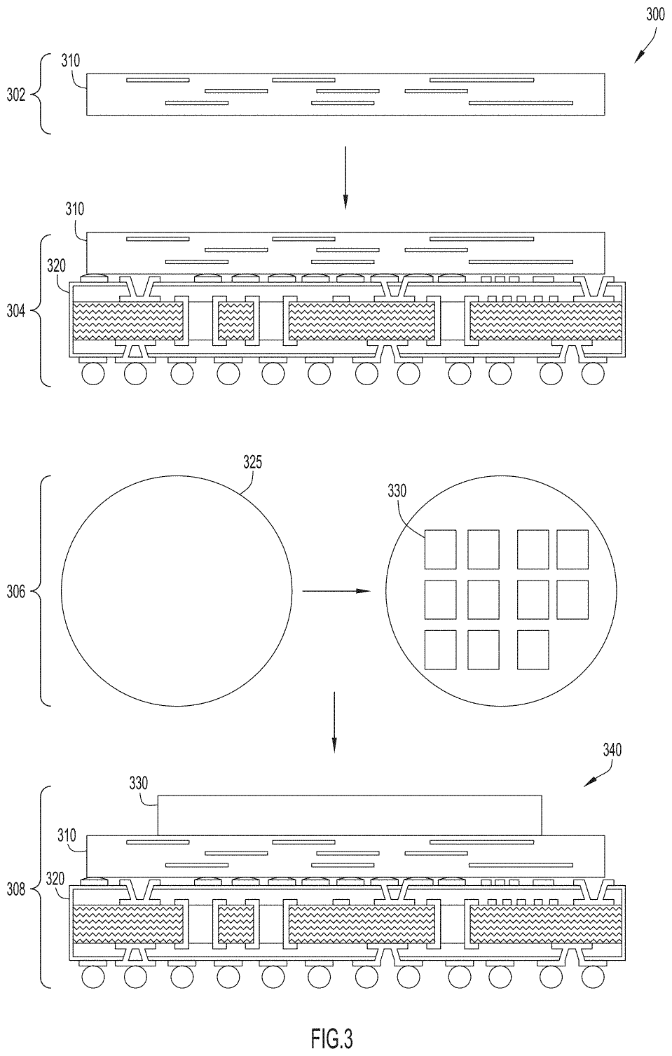

Now, present embodiments shall be described, beginning with reference to FIG. 3. FIG. 3 is a diagram depicting a workflow 300 for the fabrication of an integrated circuit package, according to an embodiment. As depicted, workflow 300 includes a first phase 302, a second phase 304, a third phase 306, and a fourth phase 308.

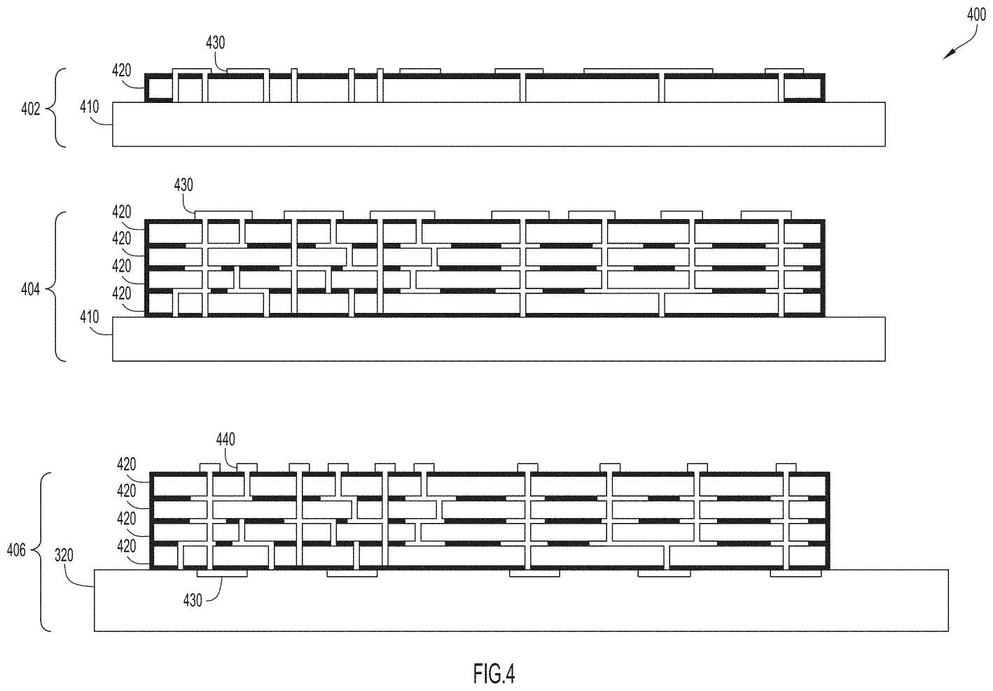

At phase 302, an interconnect structure 310 is fabricated. Interconnect structure 310 may be a thin-film interconnect structure that is composed of multiple polymeric thin-film layers, among which a conductive material (e.g., copper) is selectively provided to achieve a desired geometry for redistributing one or more IOs (e.g., in a fanout manner). Interconnect structure 310 is fabricated independently of a die, and therefore interconnect structure 310 need not be fabricated at a same facility that fabricates a die and/or substrate. The fabrication of interconnect structure 310 is depicted and described in further detail with reference to FIG. 4.

At phase 304, interconnect structure 310 is bonded to a substrate (e.g., substrate 320). The substrate may include an organic build-up substrate or other substrate. Substrate 320 is used as a base material in semiconductor applications and manufacturing. Unlike inorganic substrates, an organic substrate may be made of organic small molecules or polymers, including polycyclic aromatic compounds such as pentacene, anthracene, and rubrene.

At phase 306, a die wafer 325 is diced to individual dies (e.g., die 330). Next, die 330 is bonded to the top surface of interconnect structure 310 (e.g., the surface opposite from the surface to which substrate 320 is bonded). Accordingly, interconnect structure 310 is provided between die 330 and substrate 320 to enable redistribution of IOs, as well as other features in accordance with present embodiments. Die 330, interconnect structure 310, and substrate 320 together form assembly 340, which is an integrated circuit package. The integrated circuit may be any desired circuit, such as an ASIC, CPU, GPU, NPU, CPO, NPO, SPO, and the like.

With reference now to FIG. 4, a diagram depicting a workflow 400 is shown for the fabrication of an interconnect structure, according to an embodiment. Workflow 400 includes a first phase 402, a second phase 404, and a third phase 406. Thin-film interconnect structures fabricated in accordance with present embodiments can achieve fine pitch geometries, such as a line width/space of 2 μm/2 μm, a via/land pad diameter of 10 μm/20 μm,.

Initially, a layer 420 of thin-film polymeric material is provided to a ridge carrier 410 at phase 402. Layer 420 is a thin layer of polymeric material that is coated onto ridge carrier 410 in a large panel form. This dielectric polymeric layer is then laser-drilled, plated with a conductive material 430 (e.g., copper, silver, etc.), and patterned using a lithography tool.

At phase 404, one or more additional layers 420 are provided, one layer at a time, in a build-up manner, with each layer similarly being laser-drilled, plated with conductive material 430, and patterned to achieve a desired geometry. Once completed, this interconnect structure may be transferred to another facility (e.g., a substrate fabrication or Printed Circuit Board (PCB) facility that will complete fabrication of an integrated circuit substrate or PCB).

Once the interconnect structure is completed, the interconnect structure is provided to a substrate (e.g., substrate 320 or PCB) at phase 406. The interconnect structure is inverted when bonded to substrate 320, so that the top-most layer (e.g., the last layer to be deposited) contacts the surface of substrate 320. Additionally, ridge carrier 410 is removed. A top layer metallization 440 is provided for chip attachment. Upon completion of phase 406, dies may be added to the top surface of the interconnect structure and the integrated circuit package can be completed.

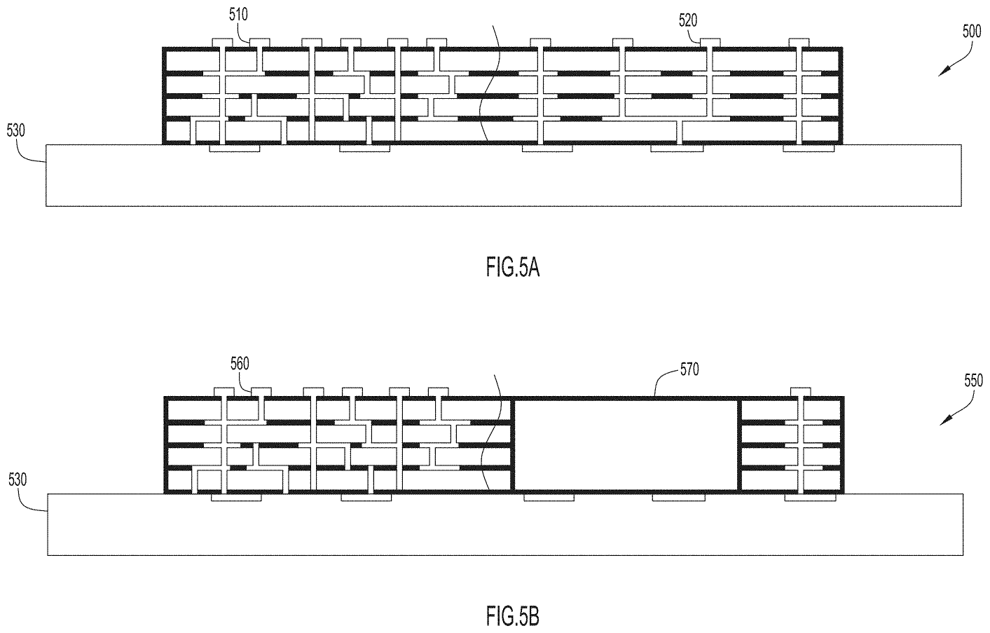

FIG. 5A is a diagram depicting an interconnect structure 500 bonded to a substrate or PCB 530, according to an embodiment. As depicted, interconnect structure 500 can include various pitches, such as finer pitch 510 and larger pitch 520. For example, finer pitch 510 may correspond to a pitch size of approximately 130 μm, whereas larger pitch 520 may correspond to a pitch size of 0.4 mm. In some embodiments, the pitch properties may vary throughout interconnect structure 500, whereas in other embodiments, the pitch properties may be substantially consistent.

FIG. 5B is a diagram depicting an interconnect structure 550 bonded to a substrate or PCB, 530 according to another embodiment. Interconnect structure 550 may include pitches of various sizes, such as finer pitch 560, which can have a pitch size of approximately 130 μm, for example. Also depicted in interconnect structure 550 is a cavity 570, which may permit a larger pitch to be directly attached between substrate or PCB 530 and a die.

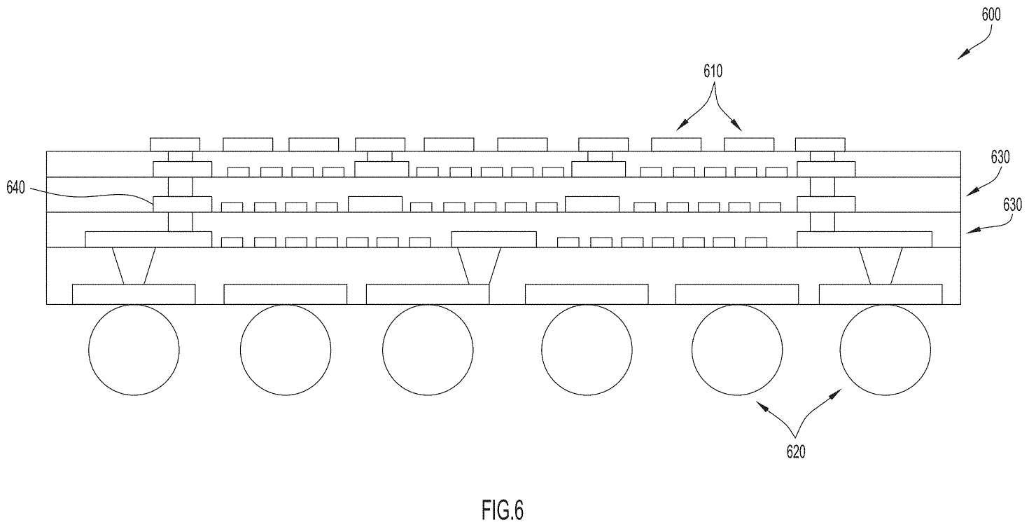

With reference now to FIG. 6, an interconnect structure 600 is depicted that includes micro-pads and micro-bumps, according to an embodiment. The interconnect structure 600, which may also be referred to as a pitch optimizer and spreader (POS), includes micro-pads 610, micro-bumps 620, multiple thin film layers 630, and vias 640. Interconnect structure 600 can replace a conventional RDL of an integrated circuit package. Recently, consumer smart devices were desired to be thinner, more energy efficient, and more cost-effective, driving technologies and processes toward thin-film technologies using a large panel format (larger than 300 mm wafer). The thin film is a polymer-based layer with copper plating to achieve fine pitch geometries. For example, line width/space of 2 μm/2 μm, via/land pad diameter of 10 μm/20 μm, and a pad pitch for die of 40 μm for a top layer and a minimum pitch of 200 μm for the bottom side. These attributes can be used to develop an RDL replacement by stacking of thin film layers 630.

Interconnect structure 600 can be built using up to five layers or more. Since interconnect structure 600 is a standalone block, interconnect structure 600 can be tested before bonding to a substrate or PCB to improve the overall yield before the next integration step. Interconnect structure 600 can be finished by adding micro-pads 610, which may be attached onto dies with micro-solder bumps and/or copper pillar bumps. Micro-pads 610 may have a pitch that ranges between, e.g., 10 μm-40 μm. Additionally, passive components, such as capacitors and/or power management elements can be integrated into the layers 630 of interconnect structure 600.

The flatness and coefficient of linear thermal expansion (CTE) of interconnect structure 600 can match traditional RDLs. Another capability of interconnect structure 600 is an increase in the body size, if desired, which can exceed 300 mm×300 mm, leveraging a standard panel size of 21 inches by 24 inches. In contrast, conventional RDLs are limited to 300 mm wafer lithography process. Additionally, the signal integrity of interconnect structure 600 may be improved as compared to conventional RDLs.

Notably, interconnect structure 600 can be designed with integrated circuit packaging tools following fewer rules and policies. This enables an OEM to develop new technologies. The properties of the geometries for the channels, and via transitions for both data and power may be set based on the desired operation of the integrated circuit. Accordingly, interconnect structure 600 can serve as a common fanout interface for all future complex chip platforms such as CPOs, NPOs, or other ASICs.

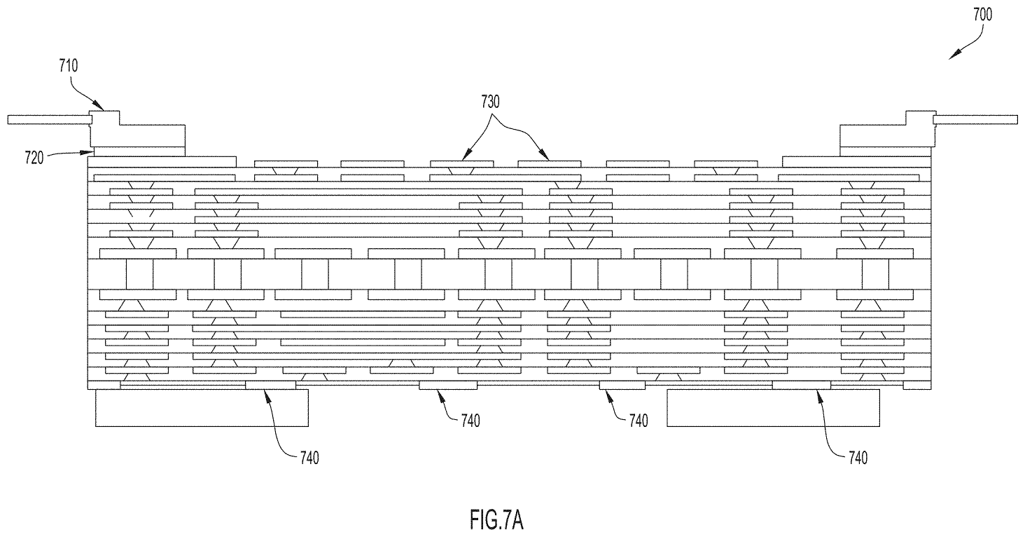

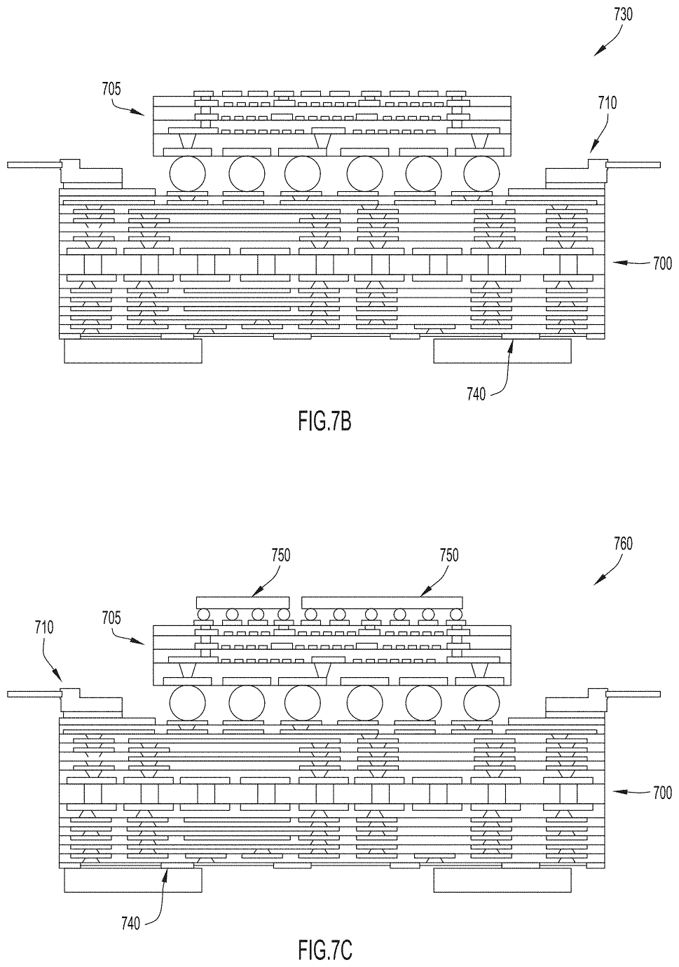

FIGS. 7A-7C are diagrams depicting a process of fabricating a CPO assembly, according to an embodiment. With reference to FIG. 7A, an example of a substrate 700 is depicted. Substrate 700, which is a CPO High Density Interconnect (HDI) substrate-like device or other board, includes assembled optical tiles 710 on the top (attached by socket 720) and different types of interconnects 740 on the bottom side, such as ball grid array (BGA) balls, sockets, mezzanine connectors, and the like. Instead of building a traditional organic substrate that has all the above limitations and concerns, an HDI technology is used. The HDI can comprise laminate materials (e.g., EM-890K) like PCB laminates, which have a low dissipation factor (Df) and relative permittivity (Dk) values compared to traditional substrate materials. A combined lamination and a modified semi-additive process (mSAP) are used to build the HDI building block. The results are quite good in terms of the IOs routing and power layers that can be added, in addition to the large body sizes (e.g., beyond 200 mm×200 mm) that can be achieved with geometries that allow the density and signal integrity benefits, e.g., linewidth/space (e.g., on a micron or sub-micron level). In terms of pad and pitch dimensions for both top and bottom layers.

The top of substrate 700 can support an interconnect structure 705, as shown in FIG. 7B, to form assembly 730. Also depicted in FIG. 7B are optical tiles 710 and interconnects 740.

The assembly 730 of FIG. 7B can be tested to ensure that assembly 730 meets a desired quality criteria before proceeding to provide dies onto the top of interconnect structure 705, as shown in FIG. 7C. FIG. 7C depicts an assembly 760 that includes dies 750, interconnect structure 705, and substrate 700, which includes optical tiles 710 and interconnects 740. Thus, an OEM may proceed in a die-last-process that improves yields, controls costs more effectively, and supports design and/or process variations.

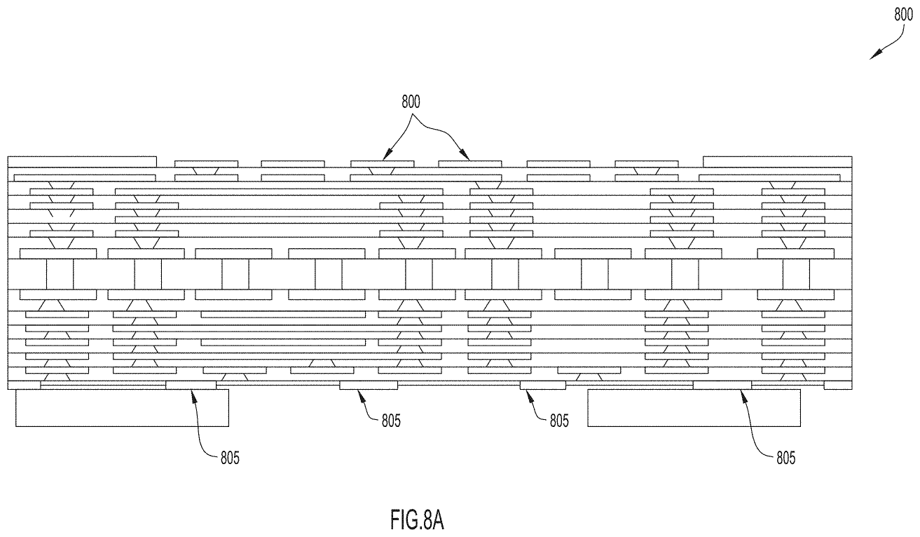

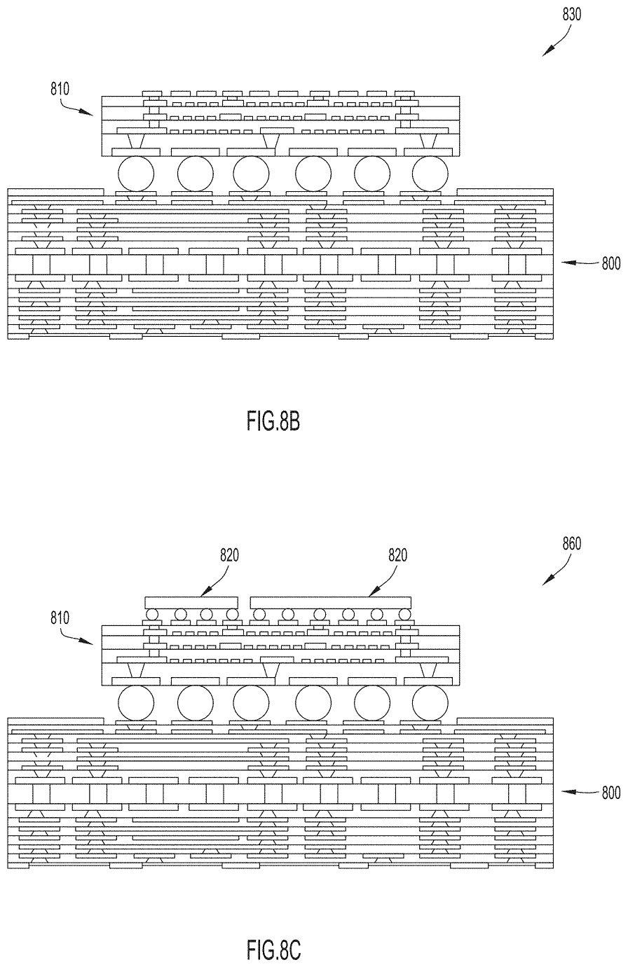

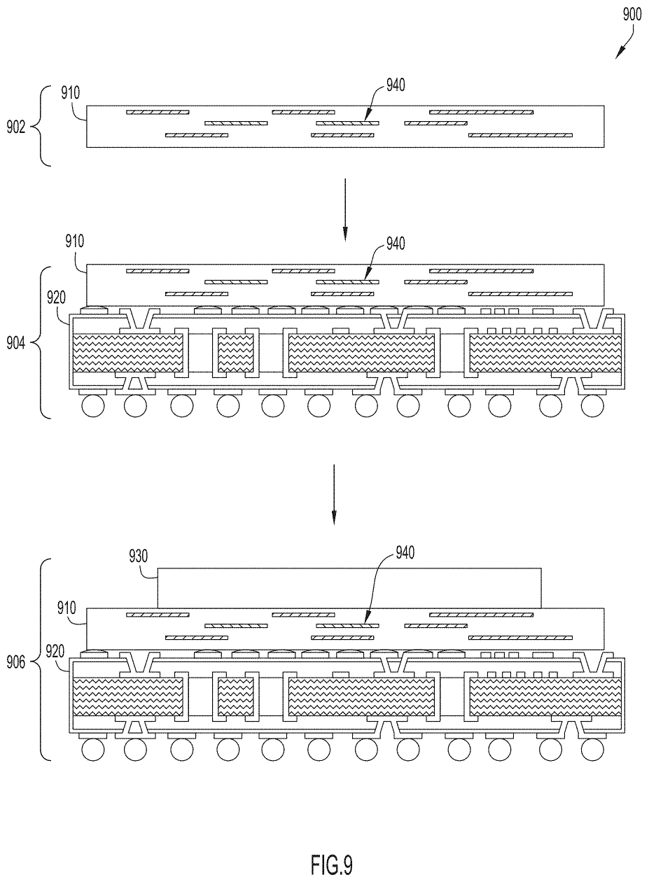

FIGS. 8A-8C are diagrams depicting a process of fabricating an ASIC assembly, according to an embodiment. Now referring to FIG. 8A, a substrate-like block 800 for an ASIC package is illustrated. Instead of using a traditional organic substrate, block 800 can be constructed using the similar process as the process described above for constructing the CPO substrate-like POS block with reference to FIGS. 7A-7C. A primary difference of the ASIC process that is depicted in FIGS. 8A-8C is that the ASIC process includes the routing of the IOs going to the bottom side of the ASIC package. Additionally, the ASIC process does not include any optical tiles. Features 805 may include various elements such as connects, sockets, and/or BGA bumps.

FIG. 8B shows assembly 830, which includes substrate-like building block 800 and an interconnect structure 810. As depicted, interconnect structure 810 is provided to the top surface of block 800. Assembly 830 can be quality tested before proceeding to the final assembly (e.g., assembly 860 of FIG. 8C).

FIG. 8C illustrates an assembly 860 that includes block 800, interconnect structure 810, and dies 820. Accordingly, assembly 860 may represent a fully-fabricated ASIC package. The architecture for present embodiments may be used for any semiconductor, such as a CPO, an SPO, an NPO, and the like. One difference between the architectures of CPO and NPO is that the NPO (in addition to having an ASIC and the optical tiles like the CPO) will also include voltage regulator modules (VRMs), necessary controllers, and passives needed to convert the main voltage rail into all the voltage rails corresponding to the ASIC and all the optical tiles.

FIG. 9 is a diagram depicting a workflow 900 for the fabrication of an integrated circuit package, according to an embodiment. At phase 902, a thin-film interconnect structure 910 is fabricated that includes one or more internal component, such as internal component 940. In various embodiments, each internal component 940 may be a capacitor or power management die that is embedded in interconnect structure 910.

At phase 904, interconnect structure 910 is bonded to substrate 920, which can include a build-up substrate, a bismaleimide triazine substrate, a PCB substrate, etc. By providing capacitors as internal components 940, the need for surface capacitors on substrate 920 is eliminated.

At phase 906, a die 930 is soldered to interconnect structure 910 to provide a completed integrated circuit package. By providing power management dies as internal components 940, many issues related to power distribution and power integrity can be addressed, thereby improving the performance of the integrated circuit.

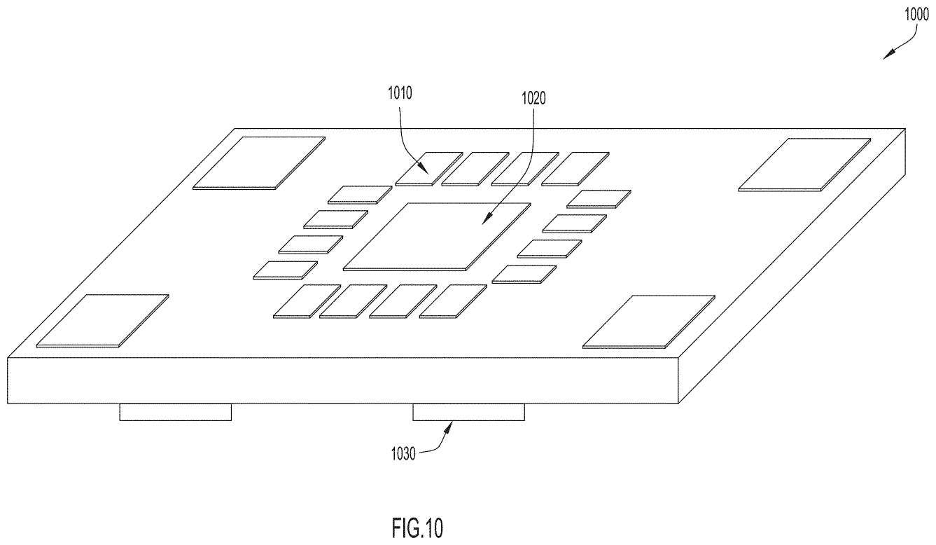

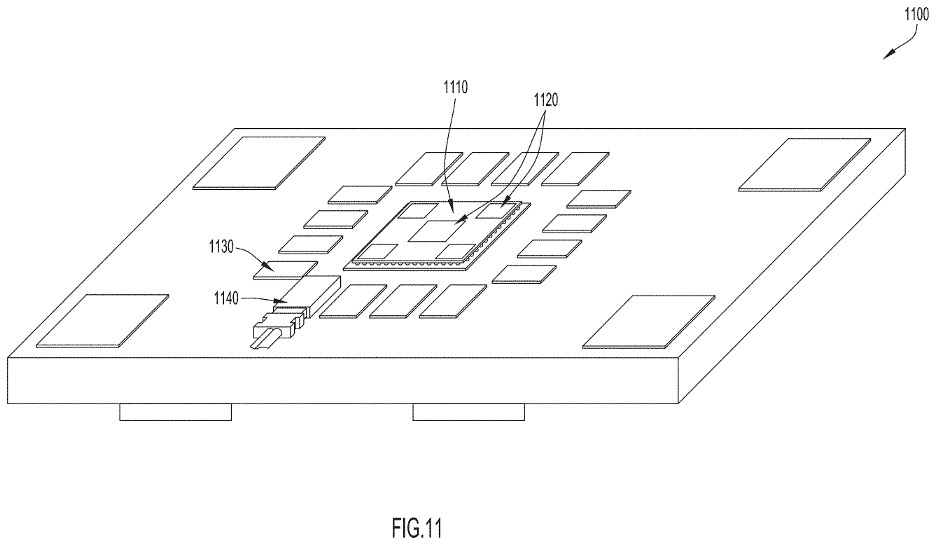

FIG. 10 is an illustration of a Near Package Optics (NPO) high density interconnection (HDI) printed circuit board (PCB)-like or substrate-like building block 1000, according to an embodiment. As depicted, block 1000 includes a socket pad array 1010 for optical tiles, a package balls field 1020, and one or more connectors or sockets 1030. An interconnect structure satisfies a number of criteria related to channel smoothness, low loss, low crosstalk, and high number of copper power planes. Two options are presented herein to achieve the complex interconnect while leveraging the interconnect structure instead of using a fully assembled ASIC

The first option for block 1000 includes the use of a substrate-like building block. The substrate-like building block uses the same architecture/design/tools as the CPO substrate-like building block. One difference is that the addition of power layers and increase in the size of the block allow for the addition of the voltage regulator modules (VRMs) and other components as mentioned above. Since these substrate-like blocks are based on a panel that may be 21 inches by 24 inches, the substrate-like block can be as large as desired. Generally, the limitations are due to the equipment used for imaging the patterns in addition to manufacturing yields due to the fine Geometries used.

A second option for block 1000 includes the use of a PCB-like building block. First, PCB-like technologies use HDI techniques and processes in advanced PCB laminates. This allows the use of dielectric materials in the PCB, including ultra-low loss materials. In addition, using advanced technologies for copper treatments and processes in the PCB reduces the surface roughness which in turn reduces the losses at high frequencies.

Both options can support building fine pad pitches as low as 0.3 mm. However, the equipment used to build the PCB-like layers and geometries may be limited in terms of how fine the geometries can be with a minimum linewidth and spacing around, e.g., 4 μm or less. Meanwhile, a substrate-like linewidth and spacing minimum may be about 14-15 μm. These are useful for reducing long channel losses that favor PCB-like building blocks compared to substrate-like building blocks in addition to the capability of adding many power layers compared to substrate-like blocks. Both options can be used to build an NPO based on a desired power copper density and channel losses. The next step is the assembly of optical tiles that follow the same process as in CPOs.

Now with reference to FIG. 11, an NPO fully-assembled ASIC 1100 is depicted, according to an embodiment. An interconnect structure 1110 is provided, which may be a common block used with any ASIC assembly. In the ASIC assembly shown in FIG. 11, interconnect structure 1110 is disposed directly on the NPO HDI PCB-like or substrate-like building block without a substrate. This will eliminate the traditional losses of the substrate, which can result in approximately a 4 dB gain. Also depicted in FIG. 11 are dies 1120 that are bonded to interconnect structure 1110, a plurality of sockets 1130, and an optical tile 1140 connected to a socket 1130.

Accordingly, a flexible semiconductor architecture based on building blocks that disaggregates the fully integrated flow used in current chip assembly is disclosed. This results in a more parallel and resilient approach that will allow manufacturers to build any chip that aligns not only with cost reduction but also with improved performance in term of signal integrity and power reduction.

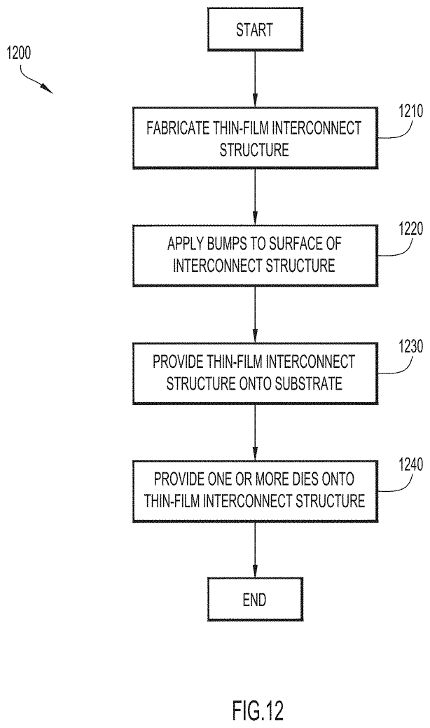

FIG. 12 is a flow chart depicting a method 1200 of assembling an integrated circuit package, according to an embodiment.

A thin-film interconnect structure is fabricated at operation 1210. The interconnect structure may be composed of several layers of a polymeric thin-film material that is deposited layer-by-layer onto a ridge carrier. After each layer is deposited, laser drilling may be conducted and a conductive plating (e.g., copper) may be provided where desired in order to achieve a particular geometry. The thin-film interconnect structure may be obtained by dividing a large panel into the thin-film interconnect structure and one or more other interconnect structures.

Bumps are applied to the surface of the interconnect structure at operation 1220. The bumps may include micro solder bumps and/or copper pillar bumps, and can be provided onto the surface of the interconnect structure that will eventually be bonded to a die (e.g., the bottom surface that is opposite of the ridge carrier.

The thin-film interconnect structure is provided onto a substrate at operation 1230. After fabrication of the thin-film interconnect structure, the thin-film interconnect structure can be transported to a facility for additional processing (e.g., bonding of substrate and dies). The thin-film interconnect structure may be inverted so that the surface having the bumps faces toward the die, and the thin-film interconnect structure and substrate may accordingly be bonded together.

One or more dies are provided onto the thin-film interconnect structure at operation 1240. The dies may be bonded to the surface of the thin-film interconnect structure opposite the other surface to which the substrate is bonded. Prior to bonding the dies, the thin-film interconnect structure-and-substrate assembly can be tested to ensure proper functionality, thereby avoiding the wasteful bonding of dies to a bad component. Once dies are bonded, fabrication of an integrated circuit package may be completed.

Reference may be made to the spatial relationships between various components and to the spatial orientation of various aspects of components as depicted in the attached drawings. However, as will be recognized by those skilled in the art after a complete reading of the present disclosure, the devices, components, members, apparatuses, etc. described herein may be positioned in any desired orientation. Thus, the use of terms such as ‘above’, ‘below’, ‘upper’, ‘lower’, ‘top’, ‘bottom’, or other similar terms to describe a spatial relationship between various components or to describe the spatial orientation of aspects of such components, should be understood to describe a relative relationship between the components or a spatial orientation of aspects of such components, respectively, as the components described herein may be oriented in any desired direction. When used to describe a range of dimensions and/or other characteristics (e.g., time, pressure, temperature, distance, etc.) of an element, operations, conditions, etc. the phrase ‘between X and Y’ represents a range that includes X and Y.

For example, it is to be understood that terms such as “left,” “right,” “top,” “bottom,” “front,” “rear,” “side,” “height,” “length,” “width,” “upper,” “lower,” “interior,” “exterior,” “inner,” “outer” and the like as may be used herein, merely describe points of reference and do not limit the present invention to any particular orientation or configuration. Further, the term “exemplary” is used herein to describe an example or illustration. Any embodiment described herein as exemplary is not to be construed as a preferred or advantageous embodiment, but rather as one example or illustration of a possible embodiment.

Further, the present disclosure may repeat reference numerals and/or letters in the various examples. This repetition is for the purpose of simplicity and clarity and does not in itself dictate a relationship between the various embodiments and/or configurations discussed. Example embodiments that may be used to implement the features and functionality of this disclosure will now be described with more particular reference to the accompanying figures.

Similarly, when used herein, the term “comprises” and its derivations (such as “comprising”, etc.) should not be understood in an excluding sense, that is, these terms should not be interpreted as excluding the possibility that what is described and defined may include further elements, steps, etc. Meanwhile, when used herein, the term “approximately” and terms of its family (such as “approximate”, etc.) should be understood as indicating values very near to those which accompany the aforementioned term. That is to say, a deviation within reasonable limits from an exact value should be accepted, because a skilled person in the art will understand that such a deviation from the values indicated is inevitable due to measurement inaccuracies, etc. The same applies to the terms “about” and “around” and “substantially”.

In some aspects, the techniques described herein relate to an apparatus including: an assembly including a substrate, one or more dies, and a thin-film interconnect structure; wherein the thin-film interconnect structure is arranged between the substrate and the one or more dies, and includes one or more polymeric layers and conductive plating.

In some aspects, the techniques described herein relate to an apparatus, wherein the thin-film interconnect structure is provided to the substrate prior to providing the one or more dies to the thin-film interconnect structure.

In some aspects, the techniques described herein relate to an apparatus, wherein the thin-film interconnect structure includes one or more thin-film capacitors.

In some aspects, the techniques described herein relate to an apparatus, wherein the thin-film interconnect structure includes one or more power management dies.

In some aspects, the techniques described herein relate to an apparatus, wherein the assembly is selected from a group consisting of: an application-specific integrated circuit, a silicon photonic packaging, a co-packaged optical module, and a near-package optical module.

In some aspects, the techniques described herein relate to an apparatus, wherein the thin-film interconnect structure is fabricated from a panel that is divided into a plurality of thin-film interconnect structures.

In some aspects, the techniques described herein relate to an apparatus, wherein the substrate includes an organic substrate.

In some aspects, the techniques described herein relate to an apparatus including: a thin-film interconnect structure that includes one or more polymeric layers and conductive plating; a first surface of the thin-film interconnect structure being configured to receive one or more dies; and a second surface of the thin-film interconnect structure being configured to receive a substrate.

In some aspects, the techniques described herein relate to an apparatus, wherein the thin-film interconnect structure includes one or more thin-film capacitors.

In some aspects, the techniques described herein relate to an apparatus, wherein the thin-film interconnect structure includes one or more power management dies.

In some aspects, the techniques described herein relate to an apparatus, wherein the thin-film interconnect structure is included in an assembly including the thin-film interconnect structure, the one or more dies, and the substrate, and wherein the assembly is selected from a group of: an application-specific integrated circuit, a silicon photonic packaging, a co-packaged optical module, and a near-package optical module.

In some aspects, the techniques described herein relate to an apparatus, wherein the thin-film interconnect structure is fabricated from a panel that is divided into a plurality of thin-film interconnect structures.

In some aspects, the techniques described herein relate to an apparatus, wherein the thin-film interconnect structure includes five or more polymeric layers.

In some aspects, the techniques described herein relate to an apparatus, wherein the first surface has a first pad pitch of at least 10 μm or, and wherein the second surface has a second pad pitch of at least 100 μm.

In some aspects, the techniques described herein relate to a method including: providing a thin-film interconnect structure onto a substrate, wherein the thin-film interconnect structure includes one or more polymeric layers and conductive plating; and providing one or more dies onto the thin-film interconnect structure.

In some aspects, the techniques described herein relate to a method, wherein the thin-film interconnect structure is provided to the substrate prior to providing the one or more dies to the thin-film interconnect structure.

In some aspects, the techniques described herein relate to a method, wherein the thin-film interconnect structure includes one or more thin-film capacitors.

In some aspects, the techniques described herein relate to a method, wherein the thin-film interconnect structure includes one or more power management dies.

In some aspects, the techniques described herein relate to a method, further including: obtaining the thin-film interconnect structure by dividing a panel into a plurality of thin-film interconnect structures.

In some aspects, the techniques described herein relate to a method, further including: providing one or more of: micro solder bumps, and copper pillar bumps to a surface of the thin-film interconnect structure.

The above description is intended by way of example only. Although the techniques are illustrated and described herein as embodied in one or more specific examples, it is nevertheless not intended to be limited to the details shown, since various modifications and structural changes may be made within the scope and range of equivalents of the claims.

What is claimed is:

1. An apparatus comprising:
an assembly comprising a substrate, one or more dies, and a thin-film interconnect structure;
wherein the thin-film interconnect structure is arranged between the substrate and the one or more dies, and comprises one or more polymeric layers and conductive plating.

2. The apparatus of claim 1, wherein the thin-film interconnect structure is provided to the substrate prior to providing the one or more dies to the thin-film interconnect structure.

3. The apparatus of claim 1, wherein the thin-film interconnect structure includes one or more thin-film capacitors.

4. The apparatus of claim 1, wherein the thin-film interconnect structure includes one or more power management dies.

5. The apparatus of claim 1, wherein the assembly is selected from a group consisting of: an application-specific integrated circuit, a silicon photonic packaging, a co-packaged optical module, and a near-package optical module.

6. The apparatus of claim 1, wherein the thin-film interconnect structure is fabricated from a panel that is divided into a plurality of thin-film interconnect structures.

7. The apparatus of claim 1, wherein the substrate includes an organic substrate.

8. An apparatus comprising:
a thin-film interconnect structure that comprises one or more polymeric layers and conductive plating;
a first surface of the thin-film interconnect structure being configured to receive one or more dies; and
a second surface of the thin-film interconnect structure being configured to receive a substrate.

9. The apparatus of claim 8, wherein the thin-film interconnect structure includes one or more thin-film capacitors.

10. The apparatus of claim 8, wherein the thin-film interconnect structure includes one or more power management dies.

11. The apparatus of claim 8, wherein the thin-film interconnect structure is included in an assembly comprising the thin-film interconnect structure, the one or more dies, and the substrate, and wherein the assembly is selected from a group of: an application-specific integrated circuit, a silicon photonic packaging, a co-packaged optical module, and a near-package optical module.

12. The apparatus of claim 8, wherein the thin-film interconnect structure is fabricated from a panel that is divided into a plurality of thin-film interconnect structures.

13. The apparatus of claim 8, wherein the thin-film interconnect structure includes five or more polymeric layers.

14. The apparatus of claim 8, wherein the first surface has a first pad pitch of at least 10 μm or, and wherein the second surface has a second pad pitch of at least 100 μm.

15. A method comprising:
providing a thin-film interconnect structure onto a substrate, wherein the thin-film interconnect structure comprises one or more polymeric layers and conductive plating; and
providing one or more dies onto the thin-film interconnect structure.

16. The method of claim 15, wherein the thin-film interconnect structure is provided to the substrate prior to providing the one or more dies to the thin-film interconnect structure.

17. The method of claim 15, wherein the thin-film interconnect structure includes one or more thin-film capacitors.

18. The method of claim 15, wherein the thin-film interconnect structure includes one or more power management dies.

19. The method of claim 15, further comprising:
obtaining the thin-film interconnect structure by dividing a panel into a plurality of thin-film interconnect structures.

20. The method of claim 15, further comprising:
providing one or more of: micro solder bumps, and copper pillar bumps to a surface of the thin-film interconnect structure.
